(19) United States
(12) Patent Application Publication
(10) Pub. No.: US 2004/0260996 A1
(43) Pub. Date: Dec. 23, 2004

(54) External coding for enhanced communications reliability

(76) Inventor: Stephen Heppe, Hood River, OR (US)

Correspondence Address: PERKINS COIE LLP, PATENT-SEA, P.O. BOX 1247, SEATTLE, WA, 98111-1247, US

(21) Appl. No.: 10/833,491

(22) Filed: Apr. 28, 2004

Related U.S. Application Data
(60) Provisional application No. 60/466,312, filed on Apr. 28, 2003.

(51) Int. Cl. H03M 13/00

(52) U.S. Cl. 714/755

(57) ABSTRACT

The present invention applies a two dimensional turbo product code to data packets handled by a data transmitting communications equipment before the data is processed by data communications equipment. The data packets are sequentially numbered and sized appropriately for transmission. The turbo product coding of the data packets allows the receiving equipment to compensate for packets that have been lost in transmission or discarded due to errors. The coding/decoding strategy may be optimized to allow for varying latency based on the severity of the errors encountered on a channel and according to the message flow rates of the transmitting equipment.

### CROSS-REFERENCE TO RELATED APPLICATION

The present application claims the benefit of pending U.S. Provisional Application Ser. No. 60/466,312, filed Apr. 28, 2003, which is incorporated herein in its entirety by reference.

### TECHNICAL FIELD

The present invention is directed to the enhancement of data communications reliability on radio frequency and other communications channels using forward error correction techniques.

### BACKGROUND

In order to increase the reliability of data communications, it is common to add codes to the transmitted data wherein the added codes are used to check and correct data at the receiving end. This process is referred to as Forward Error Correction (FEC). Numerous forward error correcting (FEC) coding techniques exist and are in wide use. Some of these methods include block or algebraic codes, convolutional codes and turbo product codes (TPC). FEC techniques may be differentiated in terms of their “power” (ability to correct errors) and their “rate” (defined as the number of information bits encoded divided by the total number of bits transmitted). A high rate, close to one, implies very little supplementary information, or “overhead” added by the FEC code. Conversely, a low rate implies that the FEC code adds many bits of supplementary information to the bits of user information. A high-rate code with high power is desirable, since such a code can correct many errors while consuming a relatively small fraction of the communications resource. Turbo product codes provide a multi-dimensional “web” of codes mutually covering a given set of bits or symbols that result in a relatively high coding rate and power.

These conventional FEC methods are applied to data immediately before being transmitted through the communications channel. For example, conventional communications equipment receives data to be transmitted, forms the data into packets, adds parity bits to the packets, adds forward error correction (FEC) information to the packets, and then modulates the packets for transmission. After the received information is demodulated, the embedded FEC codes are used to regenerate the original packets of data while ideally correcting the errors introduced by the channel (although sometimes the error correction process does not succeed in correcting all the errors in a given packet or codeword). After applying the FEC codes, the parity of the data is checked, and if the data appear correct, they are passed to the user.

At the transmitting end, it is standard practice that forward error correction encoding be performed only after the parity check sums have been calculated on the data. If the order is reversed, so that the parity processing is the last process enacted before transmission of data, the parity check must be the first process enacted at the receiver end. This would mean that FEC techniques are not applied for their primary purpose, which is to overcome transmission errors and correct data at the receiving end before a parity check occurs. If the parity check is the first process performed on received data, substantial amounts of data will be found erroneous and discarded. Therefore, prior art transmitters do not apply FEC codes before calculating parity bits.

Some “off the shelf” radio communications systems contain an embedded FEC code. While convenient from the standpoint of cost, compact design, user interfaces and equipment setup, this bundling of functions within the radio limits the flexibility of a user with respect to the application of error correction techniques. The error correction techniques are embedded inside the device such that they are typically not accessible to, or modifiable by, the user. Moreover, the error correction functions may be of limited effectiveness compared to the latest techniques known to the industry.

It is difficult for a user to insert any additional error correction functions between the commercial radio and the antenna, since the signals at this point are radio-frequency (RF). On the other hand, any attempt to add error correction before the radio at the baseband interface may be ineffective if part of the radio function is to discard blocks of data that contain errors. Furthermore, if the channel transmission rate is increased in order to accommodate extra bits of error correction information, the signal to noise ratio (SNR) of the communications channel may be reduced and cause further data losses and errors.

In addition to the problems as discussed above, some prior art radios employ a “frequency hopping” process that requires data to be divided and packetized into blocks of specific sizes. This frequency hopping process commonly results in large blocks of data being lost (e.g., if a frequency hop happens to fall on a jammed or faded frequency). These large block of lost data are difficult to fix. For these reasons it is difficult to modify or provide error detection and error correction functions using existing prior art communications systems.

Despite the difficulties of adding forward error correction, there is an incentive to do so in order to enhance information transfer reliability, throughput and the achievable communications range.

### BRIEF DESCRIPTION OF THE DRAWINGS

FIG. 1 illustrates a block diagram of a communications system of the present invention.

FIG. 2 illustrates the internal stages contained in a DCE.

FIG. 3 illustrates the processing steps and conceptual data structures contained within the processing flow of a DCE.

FIG. 4 illustrates the processing steps and conceptual data structures contained within the processing flow of both transmitting and receiving DCE's and DTE's.

FIG. 5 is a flow diagram illustrating the data transmitting process of one embodiment of the present invention.

FIG. 6 is a flow diagram illustrating the data receiving process of one embodiment of the present invention.

### DETAILED DESCRIPTION

The present system and methods provide the addition of forward error correction codes in data terminal equipment (DTE) before the data is processed by data communications equipment (DCE). The system applies two dimensional turbo product coding to packets of data in the DTE. The size of these packets of data is determined by how much data may be transmitted in one “frequency hop” employed in the DCE. Therefore, the stream of data packets already contains a forward error correction code before reaching the DCE. The DCE then may add parity bits and additional forward error correction before further packetizing and finally transmitting the data to a receiver. In order to further enhance the transmitting/receiving process, each packet of data is sequentially numbered in the DTE, or otherwise uniquely identified by an explicit or implicit process, so lost data packets may be easily identified and recreated.

A system and method is also provided to receive the forward error corrected data as described above. The receiving system demodulates the data packets, applies the forward error correction codes embedded by the transmitting DCE, performs a parity check on the data packets, and finally passes the data on to the DTE. Once in the DTE, two dimensional product decoding is applied to the data packets to reconstruct any lost or discarded data packets. The unique identification of the data packets also aids in the recreation of data. The present system therefore provides a powerful and enhanced forward error correction technique in the receiving DTE in addition to the processing performed in the receiving DCE. The present system allows for an enhanced coding/decoding strategy that maximizes data transmission rates based on the severity of the errors encountered on a channel and the message flow rates generated by the transmitting equipment.

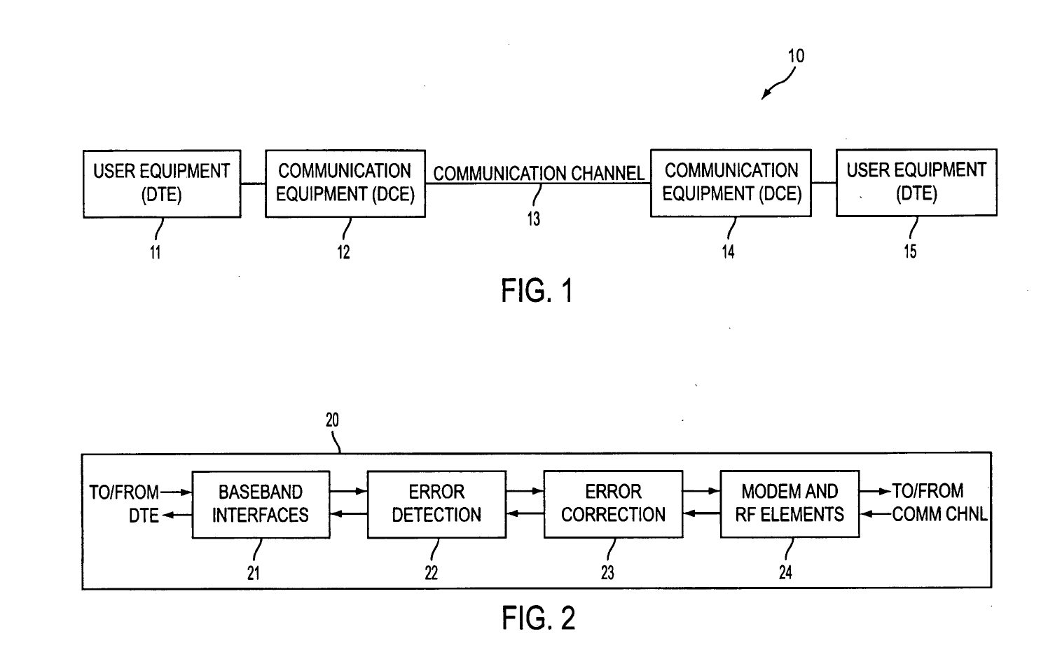

FIG. 1 illustrates a block diagram of the communications system of the present invention comprising data terminal equipment (DTE's) 11 and 15, data communications equipment (DCE's) 12 and 14, and a communications channel 13. The DTE's 11 and 15 can, for example, be computers or other equipment required to exchange information in one or both directions. DCE's 12 and 14 are communications devices that support the DTE's 11 and 15 by passing the user information (and possibly other information) over a communications channel 13. If the DCE's 12 and 14 are data radios, for example, the communications channel 13 is a radio channel. Other examples of communications channels include telephone channels and data networks. In general, the communications channel 13 can introduce errors into the data transmitted by DCE's 12 and 14.

Salient features of the communications channel 13 include the type of noise introduced by the environment, the impact of the communications channel on the signals transmitted by DCE 12 and 14, and the statistics of the errors introduced. For a radio channel, for example, the transmitted signals are typically attenuated in strength as a function of distance. The attenuation may be a simple function of range, perhaps with small random variations on the order of a few dB due to antenna pattern fluctuations or other factors. Alternatively, the variations may be large and rapid, as in a fading channel.

Noise is typically additive, although other types of noise processes are known. A common mathematical model for a channel is the so-called Additive White Gaussian Noise (AWGN) model, which comprises additive noise with a flat frequency spectrum and a Gaussian amplitude distribution. If the desired signal received by a DCE 14 is constant in amplitude, AWGN will tend to introduce errors that are uniformly scattered in time. If the desired signal received by a DCE 14 is varying in amplitude, AWGN will tend to introduce many errors when the signal is at low strength. For these reasons it is desirable to transmit information with forward error correction codes.

FIG. 2 illustrates a block diagram of the salient functions of the DCE's 12 and 14 within a radio communications system as illustrated in FIG. 1. The DCE 20 contains a baseband interface stage 21, an error detection stage 22, a forward error correction stage 23, and a modulation/demodulation stage (modem) 24. For data transmission the DCE 20 would process data from a DTE through the stages 21-24 going from left to right. Therefore, the DCE 20 takes user data and reformats and groups the user data into a packet (part of baseband interface stage 21), applies error detection overhead in 22, applies forward error correction overhead in 23, and modulates the resulting data for transmission over the communications channel in 24.

For data reception, a receiving DCE 20 would reverse and enact the stages in a right to left manner, i.e. stages 24-21. For example, a receiving DCE would receive and demodulate information from the communications channel in stage 24, decode the forward error correcting codes in stage 23, check for remaining errors in stage 22, and if the data appears to be free of errors, deliver the data to the user via the baseband interfaces in stage 21.

If the error detection stage 22 indicates an error, the data is typically discarded and not passed to the user. The receiving DCE 20 can ask for a retransmission from the transmitting DCE, or simply purge the data and await new information. In these systems where the DCE 20 is operated in such a way that users only receive information that appears free of error, the user is “at the mercy of the DCE” in terms of error control capability. This is because the user cannot enhance the forward error correction capability since errors, and the supplementary information transmitted over the channel to assist in error correction, are never passed to the user. Either the DCE 20 succeeds in receiving error-free information on the first try or subsequent ones (i.e., associated with an automatic repeat request), or it does not, and in the failure, the data is not sent to the user.

In systems where a set of user data is transmitted multiple times, the multiple transmissions may be considered a form of forward error correction coding wherein the error-free reception of any single copy represents a “good reception”. While it is possible for a user to implement this and other forms of repetition coding, such codes are relatively inefficient in terms of error correction “power” relative to the data load transmitted through the channel. For example, repetition codes require multiple transmissions of every bit and therefore consume significant channel capacity, yet offer relatively little error correction capability relative to other FEC codes.

In systems where a set of user data is transmitted once but received multiple times (e.g., receive antenna diversity), transmit power and channel capacity are conserved. The diversity receiving system can employ any one of several receiving techniques. However, if the communication system relies on separate receivers that each process a single received signal, it is not possible to achieve maximum benefit.

The present invention allows a user to enhance the forward error correction capability of a communications system using embedded DCEs, while maintaining a relatively high coding rate, and therefore a relatively high utilization efficiency on the channel.

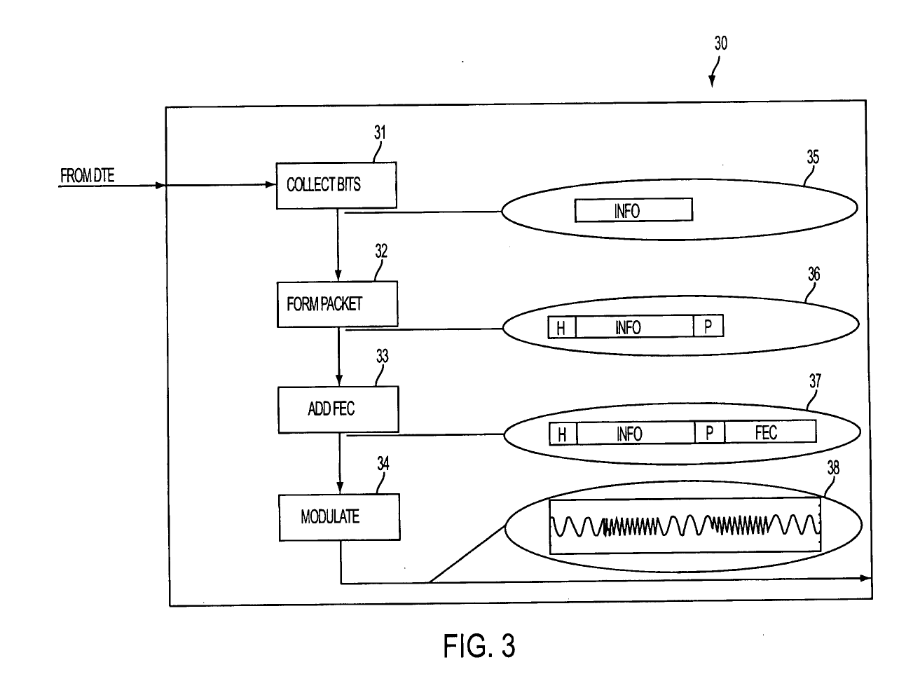

FIG. 3 illustrates a packet structure and processing flow through a DCE 30 for data to be transmitted over a radio communications channel. The state and information for the data packets are illustrated in 35-38. A group of user data bits received by a DCE 30 are collected in 31 and formed into an information (INFO) data block illustrated pictorially as 35. Next, packets 36 are formed in 32 by pre-pending the INFO block with a packet header H containing control information and appending the parity bits P that may be used to detect the presence of errors upon reception. FEC bits are added in 33 before modulating the information for transmission over the channel. In 34 the data packet 37 is modulated and transmitted to a receiver. The signal is illustrated conceptually in 38 as a few symbols of a frequency-shift-keyed waveform however many other modulation techniques are known. Sometimes different FEC codes are used for the header and non-header portions of the block 36. It is noted that the details, arrangement and ordering of bits within a transmitted packet can vary. For example the modem can encode each bit in the encoded packet as a binary symbol, or the modem can group sets of bits into higher-order symbols.

If the DCE 30 employs frequency hopping, the hop rate may be “fast” such that each transmitted symbol spans several frequency hops, or “slow” such that multiple symbols are contained within each frequency hop. Some commercial systems transmit a small, encoded packet including the associated FEC bits in a single frequency hop; hence these systems are considered slow frequency-hopping systems. In such systems, in the event that an uncorrectable error occurs during a frequency hop, all the data are lost unless the system compensates with automatic repetitions or an automatic repeat request. It is common in frequency-hopping systems to receive most frequency hops without any errors (or just one or two errors), and to completely lose the remaining frequency hops. This can occur for several reasons, but one example is where the frequency band of operation contains narrowband sources of interference (either fixed-frequency or varying in frequency). When the transmitted signal is received without overlapping in frequency with a source of interference, the data in a frequency hop are typically received without any errors (or just one or two errors). Conversely, when the frequency-hop is received along with a co-frequency interference signal, the data in that frequency hop may be received with a very large number of errors, or the receiving modem may not even synchronize with the incoming signal. If the packet 37 spans multiple frequency hops, the total loss of data within one frequency hop from within a packet may be sufficient to exceed the error correction power of the FEC codes employed for the packet.

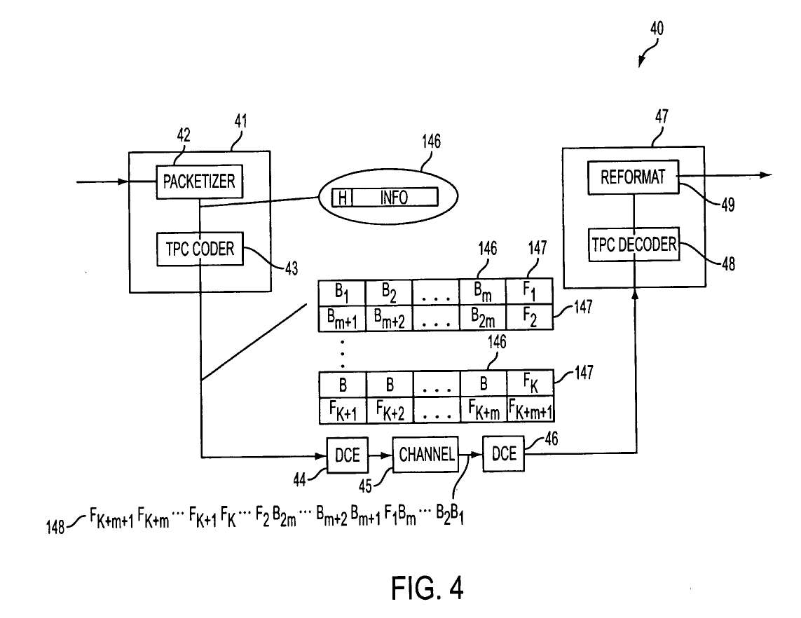

The transmitting and receiving system 40 illustrated in FIG. 4 shows one embodiment of the present invention. The communication system contains both transmitting and receiving DCE's and DTE's as described above. The transmitting DTE 41 contains a packetizer 42 and a turbo product coder (TPC) 43. The DTE 41 will provide a mechanism to enhance the information data transfer reliability by providing additional forward error correction outside and in addition to the DCE 44. The transmitting DTE 41 forms numbered blocks 146 of user data Bᵢ in the packetizer 42 wherein each block contains binary data and a header with at least a sequence number or equivalent. Each data block 146 is sized to conform to the INFO block size that can be accommodated by the DCE 44 in a single frequency hop.

According to a predetermined schedule, additional blocks 147, Fⱼ, containing FEC redundancy information, are formed by the TPC coder 43 containing FEC redundancy information. For example, the TPC coder 43 takes a block of numbered packets comprising N1 rows of N2 packets each, and encodes them using a TPC into an encoded data block of size (N1+K1)×(N2+K2). The Bᵢ and Fⱼ blocks 146 and 147 form a two-dimensional TPC code block, where the rows and columns respectively are encoded with the same or different FEC codes. The data blocks 146 and 147 are offered to the transmitting DCE 44 in temporal sequence 148 (B₁ first, F_{K+m+1} last). The DCE 44 then processes these data blocks as shown in FIG. 3, and transmits the information over the channel 45.

At the receiving end, some of the frequency hops are lost and the remaining data are presented by the receiving DCE 46 to the receiving DTE 47. The receiving DTE 47 forms the equivalent TPC code block treating the lost frequency hops as erasures (which can be identified by consideration of the sequence numbers inserted by the transmitting DTE 41). The receiving DTE 47 can then attempt to decode the TPC code block, filling in the erasures to recover the lost information. After decoding by the TPC decoder 48, the data can be reformatted in 49 before being delivered to the user. The TPC decoder 48 may be comprised of a SISO (soft-in-soft-out) buffer or the equivalent.

By delivering the packets in temporal sequence as shown in 148, the data latency in the system 40, caused by decoding, can be tailored at three levels. The first level is in the event that all user data packets 146 are received. In this case, the user information can be delivered from the DTE 47 to the user as the data packets are received. The second level is in the event that the erasure rate is very low. In this case, virtually all information contained in packets 146 can be delivered in sequence with a delay that is determined by the length of the rows in the TPC code block. The third level is that when erasures occur more frequently, virtually all information contained in packets 146 can be delivered in sequence with a delay that is determined by the total size of the TPC code block. Therefore the coding processes and algorithms of the present invention contained in the DTE's 41 and 48 may be “customized” to account for the factors described above, in order to provide data to the user at the most optimal rate. It is also noted that additional forms of frame synchronization (other than the packet numbering described above) can be employed to allow the receiving DTE 47 to form the TPC code blocks 146 and identify the locations of lost packets without departing from the sense of the present invention.

For discontinuous or low-rate information flows, the turbo product coder 43 of the present invention can be programmed to provide idling packets in order to achieve coding gain while avoiding excessive delays in end-to-end data delivery. The coder 43 may also use simple repetition codes for data flows with short messages and long temporal gaps between messages. The TPC erasure-correcting codes as applied by TPC 43 may also be tailored for longer messages and data flows that are continuous such as data flows that have multiple messages with short temporal gaps (or no gaps) between messages.

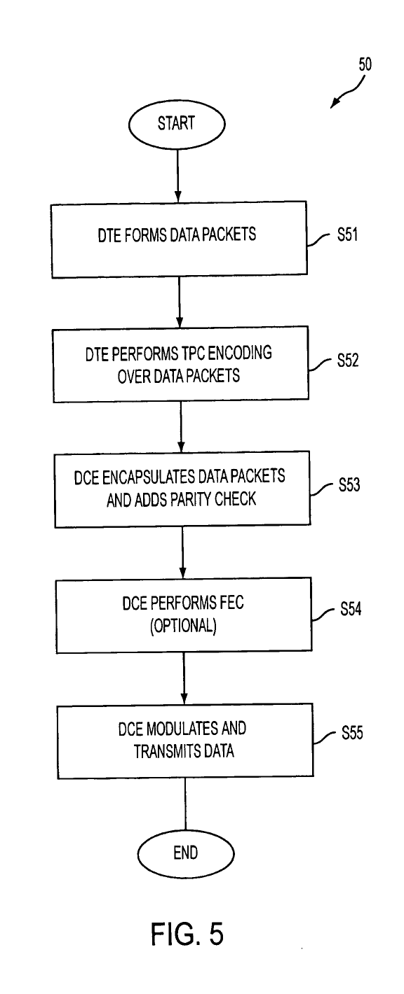

FIG. 5 is a flow diagram illustrating the steps in a transmitting process 50 of the present invention. The process 50 begins in the DTE as the DTE forms data packets of a first size in step S51. As described above, the data packets are sized in accordance with the amount of data that may be transmitted in a frequency hop used in the modulation process. The data packets are also numbered in a temporal sequence in this step. In step S52 turbo product coding techniques are applied to the data packets using a two dimensional array. After turbo product coding is finished in the DTE, the data packets are passed to the DCE for further processing.

In step S53 the DCE forms its own data packets adding header information and parity bits. In step S54 an optional forward error correction encoding is performed on the data packets in the DCE. Once this final coding is accomplished, the data packets are modulated and transmitted in step S55.

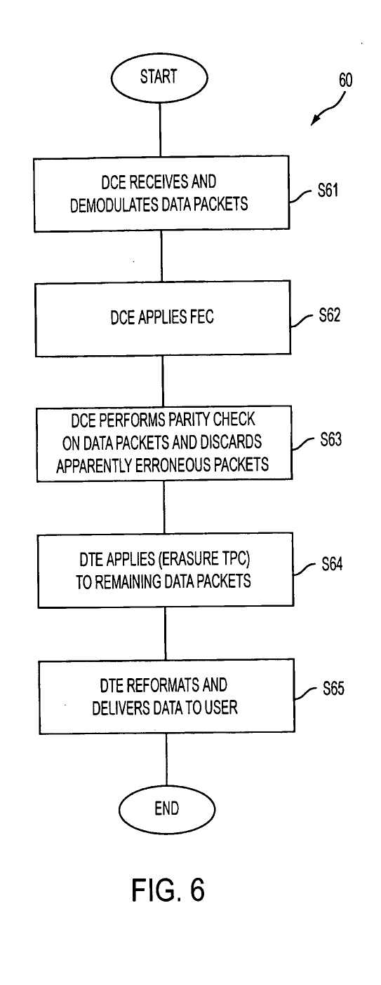

FIG. 6 is a flow diagram illustrating the steps in a receiving process 60 of the present invention. The process 60 begins in the DCE as the DCE receives and demodulates the data packets in step S61. These received data packets are then forward error corrected in step S62 using the codes embedded by the transmitting DCE. In step S63 the receiving DCE performs a parity check on the (optionally forward error corrected/decoded) data and the apparently error-free packets are passed on to the DTE for further processing. Erroneous packets of data are discarded by the DCE in step S63.

After processing by the receiving DCE, the data is further processed by the receiving DTE. In step S64 the DTE applies the “erasure TPC” to recover the lost packets. After turbo product decoding is finished, the data packets are reformatted and passed to the user for final processing in step S65.

In another preferred embodiment of the present invention, the methods of FIG. 5 and FIG. 6 may be modified to be applicable to data storage and retrieval systems. Using the DTE's and DCE's as a data storage system for example, steps S51-S54 would be enacted however the data is not transmitted or modulated in step S55, but would be stored on a disk or some other type of memory device. Therefore the data is packetized and processed as described above and the transmitting/receiving process may be replaced with a writing/reading from memory process. Referring to FIG. 6, using the DTE's and DCE's as a data storage and retrieval system, steps S62-S65 would be enacted, however since the data has not been transmitted/received, the DCE would not need to “demodulate” a data packet, but would read the data from a memory device in step S61. It is also noted that in this embodiment, given that the data packets are not actually transmitted, it may not be necessary to size the data packets in accordance with a frequency hopping process. In a data storage environment, the data packets may be appropriately sized to enhance the storage and retrieval process.

One skilled in the art will appreciate that although specific embodiments of the communications system have been described for purposes of illustration, various modifications can be made without deviating from the spirit and scope of the present invention. For example, the present invention may be applied to many different types of communications systems that employ different types of forward error correcting techniques. Accordingly, the invention is described by the appended claims.

I/We claim:

1. A system for adding forward error correction information to data to be electronically transmitted comprising:
transmitting data terminal equipment including a data packetizer for forming data packets and a turbo product code encoder that produces turbo product coded data packets; and
transmitting data communications equipment including a parity encoder, an optional forward error correction encoder, and a data modulator, wherein the transmitting data communications equipment receives the turbo product coded data packets from the transmitting DTE and performs parity encoding, optional forward error correction encoding, and modulation for transmission.

2. The system for adding forward error correction as in claim 1 wherein the data packetizer numbers the data packets in a temporal sequence.

3. The system for adding forward error correction as in claim 2 wherein the data packetizer conforms the size of the data packets to be transmitted in a single frequency hop of the data modulator.

4. The system for adding forward error correction as in claim 3 wherein the turbo product encoder encodes the data packets in a two dimensional array.

5. The system for adding forward error correction as in claim 1 wherein the turbo product coded data packets contain redundancy information.

6. A system for receiving and decoding electronically transmitted data comprising:
a receiving data communications equipment including a data demodulator, an optional forward error correction decoder, and an error detector, wherein the receiving data communications equipment demodulates and generates apparently error-free packets of data; and
a receiving data terminal equipment including a turbo product decoder and a data packet reformatter, wherein the turbo product code decoder receives the apparently error-free packets of data from the receiving data communications equipment and recovers lost data packets.

7. The system for receiving and decoding data as in claim 6 wherein the packets of data are numbered in a temporal sequence.

8. The system for receiving and decoding data as in claim 7 wherein the turbo product code decoder places the packets of data into a two dimensional array.

9. The system for receiving and decoding data as in claim 8 wherein the turbo product code decoder includes a soft-in-soft-out (SISO) buffer.

10. The system for receiving and decoding data as in claim 9 wherein the error detector discards erroneous packets of data.

11. A method for adding forward error correction information to data to be electronically transmitted comprising:
forming a first set of data packets;
creating turbo product coded data using the first set of data packets;
forming a second set of data packets with the turbo product coded data which includes parity bits;
adding forward error correction information to the second set of data packets; and
modulating and transmitting the forward error corrected second set of data packets.

12. The method for adding forward error correction as in claim 11 wherein the data packets of a first size are numbered in a temporal sequence.

13. The method for adding forward error correction as in claim 12 wherein the data packets of a first size are conformed to be transmitted in a single frequency hop used in the modulating and transmitting step.

14. The method for adding forward error correction as in claim 11 wherein the turbo product coded data is formed in a two dimensional array.

15. The method for adding forward error correction as in claim 11 further comprising the use of idling packets.

16. A method for receiving forward error corrected transmitted information comprising the steps of:
demodulating received data packets;
applying forward error correction information in the data packets to create corrected data;
performing a parity check on the corrected data to discard packets apparently containing errors and produce data packets of a second size;
applying turbo product decoding to the data packets of a second size in order to recover lost packets; and
reformatting and delivering final data to a user.

17. The method for receiving forward error corrected transmitted information as in claim 16 wherein the data packets of a second size are sequentially numbered.

18. The method for receiving forward error corrected transmitted information as in claim 17 wherein lost data packets of a second size are recreated using a two dimensional turbo product coded array.

19. The method for receiving forward error corrected transmitted information as in claim 18 wherein the step of performing a parity check includes discarding apparently erroneous data packets.

20. A method for adding forward error correction information to data to be electronically stored comprising:
forming a first set of data packets;
creating turbo product coded data using the first set of data packets;
forming a second set of data packets with the turbo product coded data; and
storing the second set of data.

21. The method for adding forward error correction as in claim 20 wherein the data packets of a first size are numbered in a temporal sequence.

22. The method for adding forward error correction as in claim 21 wherein the forward error corrected second set data packets are stored on a disk.

23. The method for adding forward error correction as in claim 20 wherein the turbo product coded data is formed in a two dimensional array.

24. The method for adding forward error correction as in claim 20 wherein the second set of data packets are sized to enhance a data storage and retrieval process.

25. A method for reading and receiving information from a data storage device comprising the steps of:
reading and receiving data packets;
optionally applying forward error correction information in the data packets to create corrected data;
performing a parity check on the corrected data to discard apparently erroneous packets and to produce data packets of apparently correct data;
applying turbo product decoding to the remaining apparently correct data in order to recover the lost data; and
reformatting and delivering final data to a user.

26. The method for reading and receiving forward error corrected information as in claim 25 wherein lost data packets of a second size are recreated using a two dimensional turbo product coded array.

27. The method for reading and receiving forward error corrected information as in claim 26 wherein the step of reading and receiving data packets includes reading the data packets from a disk.
